(19) United States
(12) Patent Application Publication
(10) Pub. No.: US 2025/0146180 A1
(43) Pub. Date: May 8, 2025

(54) POST-TREATMENT OF LITHIUM TANTALATE SINGLE CRYSTAL AND METHOD FOR MANUFACTURING LITHIUM TANTALATE SINGLE CRYSTAL SUBSTRATE USING THE SAME

(71) Applicant: Korea Photonics Technology Institute, Gwangju (KR)

(72) Inventors: Seon Hoon KIM, Gwangju (KR); Ju Hyeon CHOI, Gwangju (KR); Doo Gun KIM, Gwangju (KR); Jeong Hwan IN, Gwangju (KR); Ka Ram HAN, Gwangju (KR); So Young KIM, Gwangju (KR); Won Bae SOHN, Seoul (KR); June Hyuk KANG, Busan (KR); Jehwan HWANG, Gwangju (KR)

(73) Assignee: Korea Photonics Technology Institute, Gwangju (KR)

(21) Appl. No.: 18/916,982

(22) Filed: Oct. 16, 2024

(30) Foreign Application Priority Data
Nov. 6, 2023 (KR) 10-2023-0151412
Nov. 7, 2023 (KR) 10-2023-0152748
Apr. 9, 2024 (KR) 10-2024-0047793

(51) Int. Cl. C30B 33/02; C30B 15/00; C30B 29/30; H10N 30/04

(52) U.S. Cl. CPC C30B 33/02; C30B 15/00; C30B 29/30; H10N 30/04

(57) ABSTRACT

Disclosed is a post-treatment method of a piezoelectric oxide single crystal substrate for suppressing pyroelectric properties of the substrate, and a method for manufacturing a lithium tantalate single crystal substrate using the same. According to one aspect of the present disclosure, there is provided a post-treatment method of a piezoelectric oxide single crystal substrate, the method including: loading at least one reducing agent and the single crystal substrate into a treatment device; and performing reduction treatment by heat treating the substrate while maintaining the inside of the treatment device in a preset environment, wherein the preset environment means that heat treatment is performed at a temperature of 200° C. to 400° C. under normal pressure.

### CROSS-REFERENCE TO RELATED APPLICATIONS

This application claims priority to Korean Patent Application No. 10-2023-0151412 filed on Nov. 6, 2023, Korean Patent Application No. 10-2023-0152748, filed on Nov. 7, 2023, and Korean Patent Application No. 10-2024-0047793, filed on Apr. 9, 2024, the entire contents of which are herein incorporated by reference.

This patent is a result of research supported by the National Research Foundation of Korea and the Korea Planning & Evaluation Institute of Industrial Technology funded by the Korean government (Ministry of Science and ICT, Ministry of Trade, Industry and Energy) in 2023 to 2024 (Project Identification Number: 1711187655, Sub-Project Number: 2022M3H4A3051764, Project Title: Development of 6-inch class LiTa03 single crystal growth and heterojunction technology for radio frequency filter; Project Identification Number: 1415185269, Sub-Project Number: 20017105, Project Title: Development of CaF2 single crystal manufacturing device and 200 mm class highly homogeneous ingot technology).

### TECHNICAL FIELD

The present disclosure relates to a method for manufacturing a lithium tantalate single crystal substrate by including post-treatment of a lithium tantalate single crystal for suppressing pyroelectric properties of a lithium tantalate single crystal substrate.

### BACKGROUND ART

A description provided in this section simply provides background information for the present embodiment and does not constitute the prior art.

Lithium tantalate (LiTaO₃: hereinafter, referred to as LT) is, as a material having excellent acoustic, electro-optical, pyroelectric, ferroelectric and piezoelectric properties, a functional material used in fields such as electro-optics and acoustic optics. Particularly, a lithium tantalate (LT) single crystal that is a piezoelectric oxide is used in a surface acoustic wave (hereinafter, referred to as SAW) device, a bulk acoustic wave device, a piezoelectric transducer, a piezoelectric sensor and the like.

Meanwhile, with the rapid development of radio frequency (RF) communication systems, an RF front end is developing in directions of miniaturization, integration, high frequency, ultra-wideband, reduced frequency gap and the like. A SAW filter is an electrical filter that use acoustic waves to remove a specific frequency from a signal. With the advancement of mobile phones and the increase in the number of frequency bands, demands for a decrease in the volume are rapidly increasing in the SAW filter as well, and the number of filters required to operate with a high-quality factor and high temperature stability is also increasing.

A SAW filter has an electrode thin film made of aluminum, copper and the like formed on a substrate of a piezoelectric substrate, and the electrode thin film is formed into a predetermined-shaped electrode after going through processes such as pre-baking and post-baking in photolithography.

As described above, a lithium tantalate (LT) single crystal is a ferroelectric, and used as a main material of a SAW filter, and in order to grow a high-quality lithium tantalate (LT) single crystal, a stoichiometric lithium tantalate (LT) powder and a crystal growth process using the same are very important. By growing a high-quality lithium tantalate (LT) powder into a single crystal in an optimal environment, defects or non-uniformity of a single crystal may be minimized, and it is advantageous in growing a single crystal having target specifications and characteristics.

Meanwhile, a LT single crystal has pyroelectricity of generating charges on the surface depending on a temperature change. When a lithium tantalate (LT) single crystal is used as a piezoelectric substrate of a SAW filter, pyroelectricity of the lithium tantalate (LT) single crystal may become a problem during a filter manufacturing process.

For example, when a piezoelectric substrate is charged due to a temperature change, an electrode pattern is damaged and cracks or splits are caused in the substrate as spark discharge is generated in the piezoelectric substrate, causing a decrease in production. Such a pyroelectric effect of a lithium tantalate (LT) single crystal may neutralize charges by absorbing free charges from the surrounding environment, however, it takes several hours to completely neutralize the generated charges, and therefore, it is difficult to use a lithium tantalate (LT) single crystal in a filter manufacturing process.

In addition, since a lithium tantalate (LT) single crystal has very high light transmittance, it is difficult to achieve sufficient precision in a photolithography process for forming fine patterns.

Accordingly, in order to resolve a charging phenomenon caused by pyroelectricity of a lithium tantalate (LT) single crystal substrate, various methods for reducing it in a lithium tantalate substrate have been considered. Reduction treatment of a lithium tantalate (LT) single crystal is capable of not only suppressing a charging phenomenon of the substrate, but also increasing electrical conductivity and light absorption. On the other hand, there is an advantage in that properties of a SAW filter manufactured using a reduced substrate are not different from properties of a filter manufactured using a substrate that is not reduced.

Generally applied reduction treatment for a lithium tantalate (LT) single crystal is either heating a substrate at a high temperature or using a reducing agent, however, such reduction treatment has a problem in that process control is complicated in that reduction is performed in a high temperature and/or vacuum state and takes long period of time.

### SUMMARY

### Technical Problem

One embodiment of the present disclosure is directed to providing a method for manufacturing a piezoelectric oxide single crystal substrate capable of suppressing pyroelectric properties while maintaining properties as a piezoelectric material through post-treatment of reducing a piezoelectric oxide single crystal substrate used as a piezoelectric substrate of a SAW filter.

One embodiment of the present disclosure is directed to providing a manufacturing method capable of, while employing a heat treatment method using a reducing agent for suppressing pyroelectric properties of a piezoelectric oxide single crystal substrate, accomplishing a sufficient degree of reduction while performing heat treatment for a short period of time under normal pressure in a relatively low temperature range, and capable of accomplishing favorable productivity by manufacturing the piezoelectric oxide single crystal substrate therefrom in a relatively simple and safe manner.

One embodiment of the present disclosure is directed to providing a method for manufacturing a raw material powder used for growing a lithium tantalate (LT) single crystal used as a piezoelectric substrate of a SAW filter, the method capable of efficiently synthesizing a stoichiometric lithium tantalate (LT) powder while improving productivity through a relatively low reaction temperature and sintering for a short period of time compared to existing solid-state combustion synthesis methods.

In addition, one embodiment of the present disclosure is directed to providing a crucible for single crystal growth improving quality of a single crystal to be grown by improving insulating properties and removing impurities during the growth process, and a device including the same.

### Technical Solution

One aspect of the present disclosure provides a post-treatment method of a piezoelectric oxide single crystal substrate for suppressing pyroelectric properties of the substrate, the method including: loading at least one reducing agent and the single crystal substrate into a treatment device; and performing reduction treatment by heat treating the substrate while maintaining the inside of the treatment device in a preset environment, wherein the preset environment means that heat treatment is performed at a temperature of 200° C. to 400° C. under normal pressure.

One aspect of the present disclosure provides a method for manufacturing a lithium tantalate (LT) single crystal substrate, the method including: growing a lithium tantalate (LT) single crystal and processing the crystal into a substrate state; loading the processed lithium tantalate (LT) single crystal substrate and at least one reducing 1 agent into a treatment device; and performing reduction treatment by heat treating the substrate while maintaining the inside of the treatment device in a preset environment, wherein the preset environment means that heat treatment is performed for 3 hours to 5 hours at a temperature of 200° C. to 400° C. under normal pressure.

One aspect of the present disclosure provides a device for single crystal growth, the device including: a crucible for receiving and melting a raw material of a material to be grown as a single crystal; a cover embodied in a ring shape and seated on the top of the crucible to minimize heat release from the crucible to the outside; a crucible support unit for supporting the crucible by seating the crucible therein; a seed for growing the melted solution in the crucible into a crystal while ascending/descending and rotating; a heater disposed on the outer side of the crucible support unit to heat the crucible; an insulating material disposed on the outer side of the heater to minimize the heat released from the heater from being released in a direction away from the crucible; and a housing, wherein the cover includes a groove embodied on one surface facing the crucible with a width equal to the thickness of the outer wall of the crucible.

One aspect of the present disclosure provides a device for single crystal growth, the device including: a crucible for receiving and melting a raw material of a material to be grown as a single crystal; a cover embodied in a ring shape and seated on the top of the crucible to minimize heat release from the crucible to the outside; a crucible support unit for supporting the crucible by seating the crucible therein; a seed for growing the melted solution in the crucible into a crystal while ascending/descending and rotating; a heater disposed on the outer side of the crucible support unit to heat the crucible; an insulating material disposed on the outer side of the heater to minimize the heat released from the heater from being released in a direction away from the crucible; and a housing, wherein the cover includes a groove embodied on one surface facing the crucible with a width equal to the thickness of the outer wall of the crucible; and a heat reflecting unit embodied adjacent to the groove on the one surface on which the groove is embodied in the cover.

One aspect of the present disclosure provides a device for single crystal growth, the device including: a crucible for receiving and melting a raw material of a material to be grown as a single crystal; a crucible support unit for supporting the crucible by seating the crucible therein; a first seed for growing the melted solution in the crucible into a crystal while ascending/descending and rotating; a second seed for growing impurities included in the melted solution in the crucible into a crystal while ascending/descending and rotating; a heater disposed on the outer side of the crucible support unit to heat the crucible; an insulating material disposed on the outer side of the heater to minimize the heat released from the heater from being released in a direction away from the crucible; and a housing.

One aspect of the present disclosure provides a device for single crystal growth, the device including: a crucible for receiving and melting a raw material of a material to be grown as a single crystal; a cover embodied in a ring shape and seated on the top of the crucible to minimize heat release from the crucible to the outside; a crucible support unit for supporting the crucible by seating the crucible therein; a first seed for growing the melted solution in the crucible into a crystal while ascending/descending and rotating; a second seed for growing impurities included in the melted solution in the crucible into a crystal while ascending/descending and rotating; a heater disposed on the outer side of the crucible support unit to heat the crucible; an insulating material disposed on the outer side of the heater to minimize the heat released from the heater from being released in a direction away from the crucible; and a housing, wherein the cover includes a groove embodied on one surface facing the crucible with a width equal to the thickness of the outer wall of the crucible.

One aspect of the present disclosure provides a device for single crystal growth, the device including: a crucible for receiving and melting a raw material of a material to be grown as a single crystal; a cover embodied in a ring shape and seated on the top of the crucible to minimize heat release from the crucible to the outside; a crucible support unit for supporting the crucible by seating the crucible therein; a first seed for growing the melted solution in the crucible into a crystal while ascending/descending and rotating; a second seed for growing impurities included in the melted solution in the crucible into a crystal while ascending/descending and rotating; a heater disposed on the outer side of the crucible support unit to heat the crucible; an insulating material disposed on the outer side of the heater to minimize the heat released from the heater from being released in a direction away from the crucible; and a housing, wherein the cover includes a groove embodied on one surface facing the crucible with a width equal to the thickness of the outer wall of the crucible; and a heat reflecting unit embodied adjacent to the groove on the one surface on which the groove is embodied in the cover.

One aspect of the present disclosure provides a method for manufacturing a raw material powder for growing a piezoelectric oxide a single crystal, the method including: mixing starting materials in a preset ratio; mixing a mixture of the starting materials with an additive in a preset ratio; first sintering the mixture of the starting materials and the additive at a first temperature; and second sintering the result at a second temperature after the first sintering.

One aspect of the present disclosure provides a raw material powder for growing a piezoelectric oxide single crystal manufactured using the manufacturing method.

### Advantageous Effects

As described above, according to one aspect of the present disclosure, a pyroelectric effect, which induces a voltage increase due to an increase in the temperature and resultantly causes damage to the substrate, can be controlled by performing post-treatment of reducing a surface of the piezoelectric oxide single crystal substrate, and therefore, there is an advantage of preventing filter performance from declining when manufacturing a SAW filter using a piezoelectric oxide single crystal substrate.

According to one aspect of the present disclosure, post-treatment of a piezoelectric oxide single crystal substrate can be performed by heat treatment for a short period of time under normal pressure and a relatively low temperature condition by using a strong reducing agent in reducing the substrate, and therefore, there is an advantage in that the piezoelectric oxide single crystal substrate may be manufactured in a simpler and safer manner.

According one aspect of the present disclosure, there is an advantage of improving quality of a single crystal to be grown by improving insulating properties and removing impurities during the growth process.

According to one aspect of the present disclosure, there is an advantage in that a high-quality crystal powder can be synthesized at a relatively lower reaction temperature compared to existing solid-state combustion syntheses by adding an additive that performs an exothermic reaction during the decomposition process as an inducing agent for a binding reaction of starting materials in synthesizing a raw material powder for growing a lithium tantalate (LT) single crystal.

In addition, according to one aspect of the present disclosure, a lithium tantalate (LT) raw material powder can be obtained just by performing heat treatment for a short period of time under a relatively low temperature condition, and therefore, there are advantages in that the process can be simplified compared to existing chemical synthesis methods, process conditions can be controlled in a simpler and safer manner combustion synthesis methods, and compared to general stoichiometrically perfect lithium tantalate can be manufactured.

### DESCRIPTION OF DRAWINGS

FIG. 1 is a diagram illustrating a post-treatment device for a lithium tantalate single crystal substrate according to one embodiment of the present disclosure.

FIGS. 2A and 2B are diagrams illustrating an embodiment in which post-treatment of a lithium tantalate single crystal substrate is performed in a post-treatment device for a substrate of the present disclosure.

FIGS. 3A and 3B are diagrams illustrating a specific configuration of a reducing agent loading container provided in a post-treatment device for a substrate according to one embodiment of the present disclosure.

FIG. 4 is a flow chart illustrating a method for manufacturing substrate by post-treatment of a lithium tantalate single crystal substrate according to one embodiment of the present disclosure.

FIG. 5 shows photographs of surface states of lithium tantalate single crystal substrates subjected to post-treatment using a single reducing agent according to one embodiment of the present disclosure and a lithium tantalate single crystal substrate of Comparative Example.

FIG. 6 shows photographs of surface states of lithium tantalate single crystal substrates subjected to post-treatment using a composite reducing agent according to one embodiment of the present disclosure and a lithium tantalate single crystal substrate of Comparative Example.

FIG. 7 is a diagram illustrating a configuration of a device for single crystal growth according to one embodiment of the present disclosure.

FIG. 8 is an enlarged diagram of a portion of a crucible for single crystal growth according to one embodiment of the present disclosure.

FIG. 9 is an enlarged diagram of a portion of a crucible for single crystal growth according to another embodiment of the present disclosure.

FIGS. 10A through 10F are diagrams showing temperature distribution inside a crucible for single crystal growth during a process in which a device for single crystal growth according to one embodiment of the present disclosure grows a single crystal.

FIG. 11 is a graph showing temperature distribution of a melt in a crucible for single crystal growth according to one embodiment of the present disclosure.

FIGS. 12 and 13 are diagrams illustrating a single crystal growth process of a device for single crystal growth according to one embodiment of the present disclosure.

FIG. 14 is a flow chart illustrating a method for manufacturing a lithium tantalate raw material powder according to one embodiment of the present disclosure.

FIG. 15 shows a result of thermogravimetric-differential scanning calorimetry (TG-DSC) for analyzing a thermal response of a raw material mixture for manufacturing a lithium tantalate raw material powder according to one embodiment of the present disclosure.

FIGS. 16A and 16B are diagrams showing a temperature profile of a heat treatment process for a manufacturing process of a lithium tantalate raw material powder according to one embodiment of the present disclosure and a manufacturing process according to Comparative Example.

FIGS. 17A and 17B show photographs of lithium tantalate raw material powders manufactured using a manufacturing method according to one embodiment of the present disclosure and a manufacturing method according to Comparative Example, and results of analyzing powder compositions and crystal states by X-ray diffraction analysis (XRD).

FIGS. 18A and 18B show results of measuring lithium tantalate raw material powders manufactured using a manufacturing method according to one embodiment of the present disclosure and a manufacturing method according to Comparative Example using a scanning electron microscope (SEM).

FIGS. 19A and 19B show results of Raman spectroscopy measurements for analyzing compositions of lithium tantalate raw material powders manufactured using a manufacturing method according to one embodiment of the present disclosure and a manufacturing method according to Comparative Example.

### DETAILED DESCRIPTION

Since the present disclosure may make various changes and have various embodiments, specific embodiments will be illustrated in the drawings and described in detail. However, this is not intended to limit the present disclosure to specific embodiments, and it needs to be understood to include all changes, equivalents and substitutes included in idea and technical scope of the present disclosure. In describing each drawing, like reference numerals are used for like constituents.

Terms such as first, second, A and B may be used to describe various constituents, however, the constituents should not be limited by the terms. The terms are used only for the purpose of distinguishing one constituent from another constituent. For example, without departing from the scope of right of the present disclosure, a first constituent may be named a second constituent, and similarly, a second constituent may also be named a first constituent. The term ‘and/or’ includes a combination of a plurality of related described items or any of a plurality of related described items.

When a certain constituent is said to be “linked” or “connected” to another constituent, it needs to be understood that the certain constituent may be directly linked or connected to the another constituent, but another constituent may also be present in between. On the other hand, when a certain constituent is said to be “directly linked” or “directly connected” to another constituent, it needs to be understood that another constituent is not present in between.

Terms used in the present application are only used for describing specific embodiments, and are not intended to limit the present disclosure. Singular expressions include plural expressions unless the context clearly indicates otherwise. In the present application, terms such as “include” or “have” need to be understood as not excluding the possibility of presence or addition of features, numbers, steps, operations, constituents, components or combinations thereof described in the specification in advance.

Unless otherwise defined, all terms used herein including technical or scientific terms have the same meanings as those generally understood by those skilled in the art.

Terms defined in generally used dictionaries need to be interpreted as having a meaning consistent with the meaning in the context of related technology, and are not interpreted in an ideally or excessively formal meaning unless explicitly defined in the present application.

In addition, each constitution, process, operation, method or the like included in each embodiment of the present disclosure may be shared within the scope of not being technically contradictory to each other.

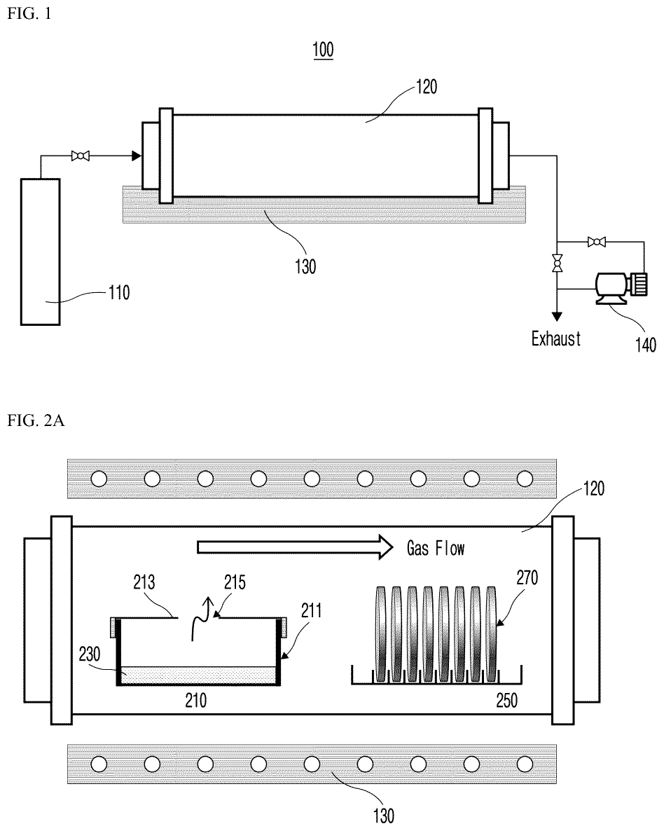

FIG. 1 is a diagram illustrating a post-treatment device for a lithium tantalate single crystal substrate according to one embodiment of the present disclosure.

The post-treatment device for a lithium tantalate single crystal substrate of the present disclosure is capable of suppressing charging of a lithium tantalate single crystal substrate by reducing a surface of the lithium tantalate single crystal using a powder-type reducing agent.

As illustrated in FIG. 1, the post-treatment device 100 for a lithium tantalate (LT) single crystal substrate according to one embodiment of the present disclosure includes a gas supply unit 110, a substrate treatment vessel 120, an electric furnace 130 and a vacuum pump 140.

The gas supply unit 110 supplies any one of air or inert gas to the substrate treatment vessel 120, so that a preset environment for reducing the lithium tantalate (LT) single crystal substrate is maintained inside the substrate treatment vessel 120.

For this, the gas supply unit 110 may continuously supply gas to the substrate treatment vessel 120 while reducing the lithium tantalate single crystal substrate.

Air or inert gas may be used for the reduction reaction of the lithium tantalate single crystal substrate, however, it is more preferred to supply inert gas in order to more sufficiently reduce the lithium tantalate substrate.

When the gas supply unit 110 supplies inert gas, gas such as nitrogen (N₂), argon (Ar) or helium (He) may be used as an example of the inert gas, and it is preferred to use nitrogen (N₂) gas that is relatively inexpensive and easy to handle.

The substrate treatment vessel 120 receives gas from the gas supply unit 110, and loads a lithium tantalate (LT) single crystal substrate 270 and a reducing agent 230 to be described later thereinto to reduce the surface of the lithium tantalate (LT) single crystal substrate.

The substrate treatment vessel 120 may be made of quartz, and both sides thereof are connected by pipes. The pipe on one side of the substrate treatment vessel 120 receives gas from the gas supply unit 110 and the pipe on the other side is connected to the vacuum pump 140 to perform exhaust in the substrate treatment vessel 120 after the reaction is completed.

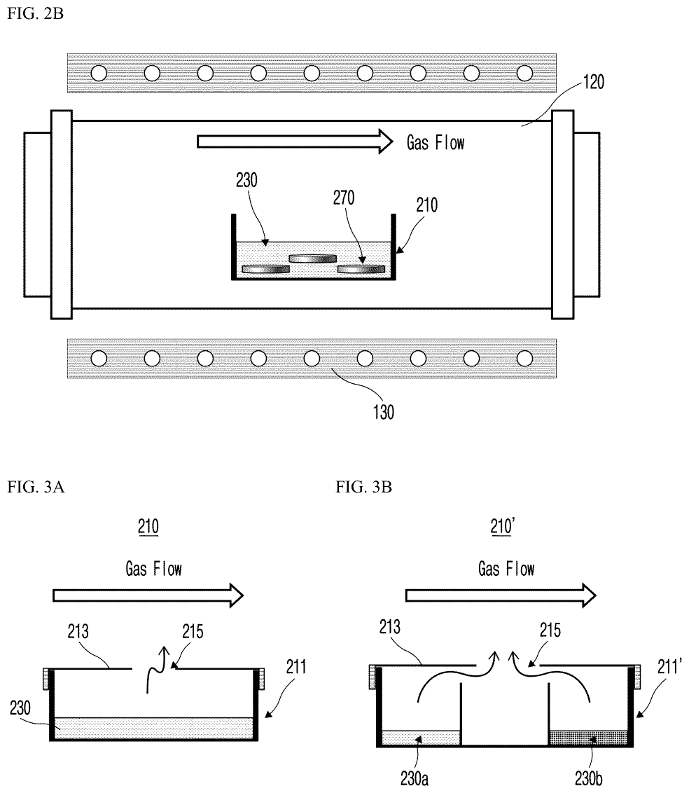

The substrate treatment vessel 120 accommodates a lithium tantalate (LT) single crystal substrate 270 and a reducing agent 230 therein, and the specific configuration of the substrate treatment vessel 120 in which these are accommodated will be described later referring to FIG. 2.

The electric furnace 130 is disposed around the substrate treatment vessel 120, and raises the temperature inside the substrate treatment vessel 120 to a preset range.

For this, the electric furnace 130 may be disposed in a form of surrounding the outer circumference surface of the substrate treatment vessel 120. Herein, the preset temperature at which the lithium tantalate (LT) single crystal substrate is reduced may be selected in a range of 200° C. to 400° C.

Meanwhile, since the lithium tantalate (LT) single crystal has a Curie temperature of approximately 603° C., piezoelectricity may be damaged when the lithium tantalate single crystal is exposed to a high temperature of 600° C. or higher. Accordingly, the reduction treatment of the lithium tantalate single crystal is usually performed in a range of 400° C. to 600° C., and the heat treatment is performed so that only the surface of the substrate is reduced.

However, as described above, the reduction of the lithium tantalate (LT) single crystal substrate is performed in a temperature range of 200° C. to 400° C. in the present disclosure, and therefore, there is a technical feature that the lithium tantalate (LT) single crystal is sufficiently reduced in a relatively low-temperature environment.

The vacuum pump 140 is connected to the pipe connected to the other side of the substrate treatment vessel 120, and performs exhaust of the gas inside the substrate treatment vessel 120. The vacuum pump 140 is linked to a valve disposed in the pipe, and exhausts the gas inside the substrate treatment vessel 120 when the reduction treatment of the substrate is completed.

FIGS. 2A and 2B are diagrams illustrating a form in which the lithium tantalate (LT) single crystal substrate reacts with a reducing agent and undergoes post-treatment in the substrate post-treatment device of the present disclosure.

FIG. 2A shows a structure in which the lithium tantalate (LT) single crystal substrate 270 and the reducing agent 230 are loaded into the substrate treatment vessel 120 according to a first embodiment of the present disclosure, and FIG. 2B shows a structure in which the lithium tantalate (LT) single crystal substrate 270 and the reducing agent 230 are loaded into the substrate treatment vessel 120 according to a second embodiment of the present disclosure.

Referring to FIG. 2A, the reduction treatment of the lithium tantalate (LT) single crystal substrate according to the first embodiment of the present disclosure may be performed by independently disposing a reducing agent loading container 210 and a substrate support 250 inside the substrate treatment vessel 120.

The reducing agent loading container 210 is formed with a container body 211 forming a space in which the reducing agent 230 is disposed therein. In addition, the reducing agent loading container 210 may further include a container cover 213, and the container cover 213 may have at least one hole 215 in the middle to allow the reducing agent 230 to be discharged to the outside of the reducing agent loading container 210.

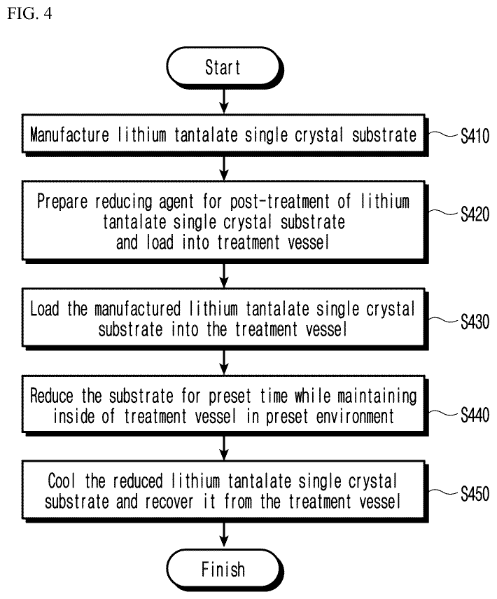

At least one type of reducing agent 230 may be loaded into the reducing agent loading container 210, and examples of the loading container 210 depending on the number of reducing agents are illustrated in FIG. 3.

FIGS. 3A and 3B are diagrams illustrating a specific configuration of the reducing agent loading container used in the post-treatment method of the substrate of the first embodiment of the present disclosure.

FIG. 3A shows the reducing agent loading container 210 according to one embodiment used in the post-treatment method of the first embodiment, and FIG. 3B shows a reducing agent loading container 210′ according to another embodiment used in the post-treatment method of the first embodiment.

The reducing agent loading container 210 according to one embodiment includes a container body 211 and a container cover 213 as described above, and has a space into which one type of reducing agent 230 is loaded formed therein.

On the other hand, the reducing agent loading container 210′ according to another embodiment of FIG. 3B may have at least two or more types of reducing agents 230a, 230b loaded thereinto. Herein, at least two or more types of reducing agents 230a, 230b are separately disposed inside the container body 211′ depending on the type, and for this, the container body 211′ may be provided with a baffle 217 therein to be divided into a plurality of spaces.

Referring to FIG. 2A again, the substrate support 250 supports the substrate 270 so that at least one lithium tantalate (LT) single crystal substrate 270 is treated by the reducing agent 230 inside the substrate treatment vessel 120. For this, the substrate 270 may have a structure of including a plurality of insertion holes, and having the unit substrate 270 installed in each of the insertion holes.

The reducing agent loading containers 210, 210′ and the substrate support 250 may be formed of quartz or alumina. In addition, the reducing agent loading containers 210, 210′ are preferably disposed relatively upstream compared to the substrate support 250 inside the substrate treatment vessel 120. In other words, depending on the flow of the gas introduced from one side of the substrate treatment vessel 120, the reducing agent loading containers 210, 210′ are disposed so that at least one type of reducing agent 230 is brought into contact with the surface of the lithium tantalate (LT) single crystal substrate 270 while moving.

Meanwhile, the reduction treatment of the lithium tantalate (LT) single crystal substrate according to the second embodiment of the present disclosure may be performed while the lithium tantalate (LT) single crystal substrate 270 is embedded in the reducing agent 230.

Referring to FIG. 2B, in the reduction treatment of the second embodiment, the reducing agent loading container 210 having a space, in which a reducing agent is accommodated, formed therein is disposed inside the substrate treatment vessel 120.

Herein, a powder-type reducing agent 230 is loaded into the reducing agent loading container 210, and at least one of the substrates 270 may be embedded in the powder-type reducing agent 230.

The reduction treatment of the second embodiment may also use at least one type of reducing agent 230, and the at least one type of reducing agent has a powder form, and these may be disposed inside the reducing agent loading container 210 in a mixed powder form.

Hereinafter, a method for manufacturing a substrate including the post-treatment method of the lithium tantalate (LT) single crystal substrate that is a piezoelectric oxide according to one embodiment of the present disclosure, will be described.

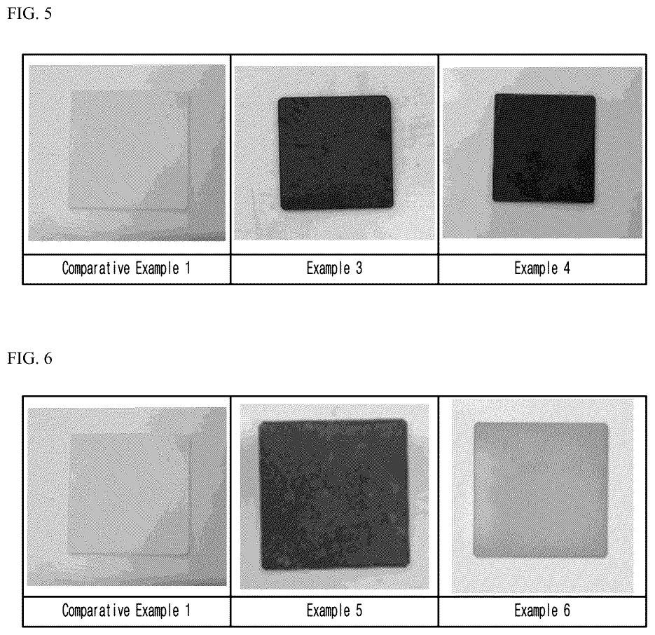

FIG. 4 is a flow chart illustrating a method for manufacturing a lithium tantalate (LT) single crystal substrate according to one embodiment of the present disclosure by post-treatment.

A lithium tantalate (LT) single crystal substrate is manufactured (S410).

In the lithium tantalate (LT) single crystal substrate, a lithium tantalate single crystal is grown using a Czochralski method using a raw material having a congruent composition, and the ingot obtained herein has a transparent light-yellow color.

A Czochralski method may be used for the lithium tantalate (LT) single crystal substrate according to one embodiment of the present disclosure, and a specific configuration of a device for single crystal growth used therefor, and a method for preparing a stoichiometric lithium tantalate (LT) raw material powder forming the congruent composition loaded into the device for single crystal growth will be described later.

The obtained ingot is subjected to poling treatment, and formed into a lithium tantalate (LT) substrate through processes such as grinding and slicing. The manufactured substrate is colorless and transparent, and has specific resistance in a range of 10¹⁵ Ω·cm or greater.

A reducing agent for post-treatment of the lithium tantalate (LT) single crystal substrate is prepared, and loaded into a substrate treatment vessel (S420).

In the present disclosure, a powder-type reducing agent may be used as the reducing agent for reducing the lithium tantalate (LT) single crystal substrate, and the powder-type reducing agent 230 is loaded into the substrate treatment vessel 120 while being accommodated in a reducing agent loading container 210.

In the present disclosure, at least one type of reducing agent may be used for reduction treatment of the lithium tantalate (LT) single crystal substrate.

In the present disclosure, sodium borohydride (NaBH₄) may be used as the reducing agent for post-treatment of the lithium tantalate (LT) single crystal substrate. Sodium borohydride (NaBH₄) is a strong reducing agent mainly used in the paper and dye industries, and may be readily decomposed under a relatively mild condition to produce hydrogen (H₂) molecules.

In addition, as the powder-type reducing agent used for reduction treatment of the lithium tantalate (LT) single crystal substrate, aluminum (Al), lithium carbonate (Li₂CO₃), iron (Fe), aluminum oxide (Al₂O₃), lithium chloride (LiCl) and the like may be further included, and any one or more of these powder-type reducing agents may be selected and used as the reducing agent together with sodium borohydride (NaBH₄).

Herein, when two or more types of reducing agents including sodium borohydride (NaBH₄) are used as the reducing agent for post-treatment of the lithium tantalate (LT) single crystal substrate, the sodium borohydride (NaBH₄) may be included in a range of 10% to 90% of the total weight of the powder-type reducing agent.

The manufactured lithium tantalate (LT) single crystal substrate is loaded into the substrate treatment vessel 120 (S430).

The lithium tantalate (LT) single crystal substrate 270 may be loaded into the substrate treatment vessel 120 while being disposed inside the substrate treatment vessel 120 by being supported by the substrate support 250, or while being embedded agent 230 in a powder state after being in the reducing accommodated together with the reducing agent 230 in the reducing agent loading container 210.

The substrate is reduced for a preset time while maintaining the inside of the substrate treatment vessel 120 in a preset environment (S440).

When the reducing agent 230 in a powder state and the lithium tantalate (LT) single crystal substrate 270 are all loaded into the substrate treatment vessel 120, the substrate treatment vessel 120 is heated using the electric furnace 130 to create a preset environment inside the substrate treatment vessel 120.

In order for the lithium tantalate (LT) single crystal substrate to be sufficiently reduced by the reducing agent, the inside of the substrate treatment vessel 120 may be heat treated for 7 hours or shorter under normal pressure and in a temperature range of 200° C. to 400° C. under the air or inert gas atmosphere. Particularly, it is more preferred to maintain the inside of the substrate treatment vessel 120 for 2 hours to 5 hours under normal pressure and at a temperature in a range of 200° C. to 400° C. under the inert gas atmosphere.

As the inert gas, any one of nitrogen (N₂), argon (Ar) and helium (He) may be selected and used, and the inert gas is supplied from the gas supply unit 110 when starting to raise the temperature inside the substrate treatment vessel 120.

A general environment for reducing a lithium tantalate (LT) single crystal substrate using a reducing agent is that heat treatment is usually performed for 1 hour to 24 hours in a temperature range of 400° C. to 600° C. under reduced pressure. On the other hand, the reduction treatment of lithium tantalate (LT) single crystal substrate of the present disclosure uses sodium borohydride (NaBH₄), a strong reducing agent, as a main reducing agent, and therefore, the reduction treatment of the substrate may be performed in a short period of time under normal pressure in a relatively low temperature range.

The reduced lithium tantalate (LT) single crystal substrate is cooled, and then recovered from the substrate treatment vessel 120 (S450).

When the preset time for reduction treatment passes, the electric furnace 130 is stopped and the heat treatment is completed, and the gas inside the substrate treatment vessel 120 is exhausted to the outside by the vacuum pump 140. In addition, as the inside of the substrate treatment vessel 120 is naturally cooled to room temperature, the manufacture of the reduced lithium tantalate (LT) single crystal substrate is finished.

The sufficiently reduced lithium tantalate (LT) single crystal substrate may be changed to opaque black, gray or gray-black in color, and from this, high light transmittance of a transparent substrate before the reduction treatment may be suppressed.

Hereinafter, examples of the reduction treatment of the lithium tantalate (LT) single crystal substrate using the post-treatment method of the lithium tantalate (LT) single crystal substrate of one embodiment of the present disclosure will be described.

### (1) Post-Treatment of Lithium Tantalate (LT) Single Crystal Substrate Using Sodium Borohydride (NaBH₄) as Reducing Agent

Sodium borohydride (NaBH₄) in a powder state was used as a reducing agent, and a lithium tantalate (LT) single crystal was prepared using lithium carbonate (Li₂CO₃) and tantalum pentoxide (Ta₂O₅) as raw materials.

A lithium tantalate (LT) single crystal substrate processed into a substrate form from the prepared single crystal was loaded into a substrate treatment vessel 120 together with sodium borohydride (NaBH₄), and while varying heat treatment temperature and time in a range of 200° C. to 400° C., post-treatment of the substrate was performed. Herein, the inside of the substrate treatment vessel 120 was maintained under normal pressure and the nitrogen atmosphere by supplying nitrogen (N₂) as inert gas. Through the heat treatment process, hydrogen (H₂) molecules are produced while sodium borohydride (NaBH₄) is decomposed, and from this, the surface of the lithium tantalate (LT) single crystal substrate is reduced.

A series of processes for forming the lithium tantalate single crystal substrate and performing post-treatment (LT) through heat treatment thereon with the reducing agent were performed by steps S410 to S450.

For the post-treated lithium tantalate (LT) single crystal substrate, a specific resistance value was measured in order to determine whether the reduction treatment was sufficiently performed, and the reduced lithium tantalate (LT) single crystal substrates of Examples were compared with the lithium tantalate (LT) single crystal substrate that had not undergone the post-treatment process as Comparative Example.

As Examples in which the post-treatment of the substrate is performed using sodium borohydride (NaBH₄) as a single reducing agent, the following Table 1 shows results of measuring specific resistance of the substrates that had undergone the post-treatment by performing heat treatment under normal pressure and the nitrogen (N₂) gas atmosphere, while varying the heat treatment temperature and the retaining time.

TABLE 1

| | Category | | | |
|---|---|---|---|---|
| | Heat | | | |
| | Treatment | | Heat | Specific |
| | Temperature | | Treatment | Resistance |
| | (° C.) | Atmosphere | Time (hr) | (Ω · cm) |
| Comparative | — | — | — | 4.4 × 10¹⁶ |
| Example | | | | |
| Example 1 | 200 | Nitrogen (N₂) | 5 | 1.6 × 10¹⁶ |
| Example 2 | 300 | Nitrogen (N₂) | 5 | 3.3 × 10¹² |
| Example 3 | 400 | Nitrogen (N₂) | 5 | 4.5 × 10¹¹ |
| Example 4 | 400 | Nitrogen (N₂) | 3 | 2.8 × 10¹² |

While maintaining the environment in which the substrate was reduced under normal pressure and the nitrogen (N₂) atmosphere, the lithium tantalate (LT) single crystal substrate was reduced with sodium borohydride (NaBH₄) powder by performing heat treatment for 5 hours while changing the heat treatment temperature from 200° C. to 400° C., and as a result, it was able to be identified that the specific resistance value decreased to a level of less than 1013 Ω·cm compared to the value of the substrate that had not undergone reduction treatment (specific resistance value 4.4×10¹⁶ Ω·cm), and it was able to be seen that the substrate was reduced.

Particularly, the results of Examples 1 to 3 in which the heat treatment was equally applied for the 5 hours show that the specific resistance value of the lithium tantalate (LT) single crystal substrate gradually decreases as the heat treatment temperature increases, and therefore, it may be identified that the degree of reduction of the substrate increases as the heat treatment temperature increases, and thus the effect of charging suppression of the lithium tantalate (LT) single crystal substrate becomes greater. Furthermore, from the specific resistance value of the substrate depending on the heat treatment temperature presented in Table 1, it is considered that the reduction treatment of the substrate using sodium borohydride (NaBH₄) powder of the present disclosure is sufficiently achieved at 300° C. or higher.

Meanwhile, even when normal pressure and nitrogen (N₂) atmosphere were maintained at a temperature of 400° C. and the heat treatment time was 3 hours (Example 4), the specific resistance value was measured at a similar level to when the heat treatment was performed for 5 hours, and it may be seen that the lithium tantalate (LT) single crystal substrate is able to be sufficiently reduced even when the heat treatment time is shortened to 3 hours.

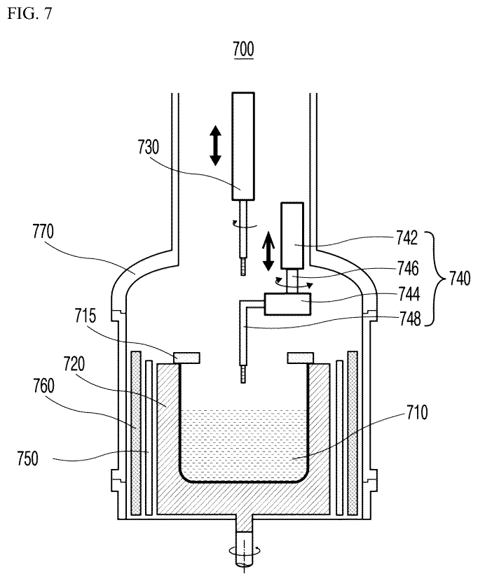

Meanwhile, light transmittance may be suppressed by reducing the surface of the lithium tantalate (LT) single crystal substrate, and this may also be identified in FIG. 5.

FIG. 5 shows photographs of surface states of the lithium tantalate (LT) single crystal substrates that had undergone post-treatment using sodium borohydride (NaBH₄), a single reducing agent, according to one embodiment of the present disclosure and the lithium tantalate (LT) single crystal substrate of Comparative Example.

Referring to FIG. 5, it may be seen that the lithium tantalate (LT) single crystal substrate of Comparative Example, which was not subjected to reduction treatment, is transparent.

However, it may be seen that the lithium tantalate (LT) single crystal substrates of Example 3 (heat treatment for 5 hours) and Example 4 (heat treatment for 3 hours) in which heat treatment was performed while maintaining normal pressure and nitrogen (N₂) atmosphere at a temperature of 400° C. were black and opaque, and therefore, it may be seen that light transmittance was also suppressed compared to in the substrate before reduction treatment.

In the lithium tantalate (LT) single crystal substrate, electrical conductivity increases by 4 times to 5 times and the specific resistance value may be reduced to a level of 10⁹ Ω·cm to 10¹² Ω·cm through the reduction treatment, and as a result, the substrate may be processed to a level suitable to be used as a piezoelectric substrate of a SAW filter.

The post-treatment method of the lithium tantalate (LT) single crystal substrate of the present disclosure uses only sodium borohydride (NaBH₄) as a reducing agent so that the lithium tantalate (LT) single crystal substrate is reduced under normal pressure in a relatively low temperature range, and particularly, is capable of performing reduction treatment at a level of sufficiently suppressing charging of the lithium tantalate (LT) single crystal substrate while shortening the heat treatment time to 5 hours or shorter, more preferably to 3 hours.

### (2) Post-Treatment of Lithium Tantalate (LT) Single Crystal Substrate Using Two Types of Reducing Agents Including Sodium Borohydride (NaBH₄)

As a reducing agent, any one of lithium carbonate (Li₂CO₃) powder or aluminum oxide (Al₂O₃) powder was selected and used together with sodium borohydride (NaBH₄) in a powder state. Herein, the sodium borohydride (NaBH₄) may be loaded into the substrate treatment vessel 120 in a ratio of 90 wt % to 10 wt % of the total reducing agent weight, and the any one reducing agent selected from lithium carbonate (Li₂CO₃) powder and aluminum oxide (Al₂O₃) powder and used may be loaded thereinto in a ratio of 10 wt % to 90 wt %, and in Example 5 and Example 6, 50 wt % of the sodium borohydride (NaBH₄) and 50 wt % of the another reducing agent were loaded into the substrate treatment vessel 120.

In addition, heat treatment for reduction treatment was performed for 3 hours at 300° C., and as in Examples 1 to 4, the inside of the substrate treatment vessel 120 was maintained under normal pressure and the nitrogen atmosphere by supplying nitrogen (N₂) gas as inert gas.

A series of processes for forming the lithium tantalate (LT) single crystal substrate including preparation of the lithium tantalate (LT) single crystal and performing post-treatment thereon through heat treatment together with the reducing agents were also performed by steps S410 to S450 as in Examples 1 to 4.

The following Table 2 shows results of measuring specific resistance of the substrate in Examples in which post-treatment of the substrate is performed using two types of reducing agents including sodium borohydride (NaBH₄).

TABLE 2

| | Category | | | | |
|---|---|---|---|---|---|
| | | Heat | | Heat | |
| | Type of | Treatment | | Treatment | Specific |
| | Reducing | Temperature | Atmo- | Time | Resistance |
| | Agent | (° C.) | sphere | (Hour) | (Ω · cm) |
| Comparative | — | — | — | — | 4.4 × 10¹⁶ |
| Example | | | | | |
| Example 5 | NaBH₄ | 300 | N₂ | 3 | 4.5 × 10⁹ |
| | Li₂CO₃ | | | | |
| Example 6 | NaBH₄ | 300 | N₂ | 3 | 5.0 × 10¹¹ |
| | Al₂O₃ | | | | |

Unlike in Examples 1 to 4, the lithium tantalate (LT) single crystal substrate was reduced using two types of reducing agents further including another reducing agent in addition to the sodium borohydride (NaBH₄) powder as the reducing agent in Examples 5 and 6.

The lithium tantalate (LT) single crystal substrate that had undergone reduction treatment by further adding any one of lithium carbonate (Li₂CO₃) powder or aluminum oxide (Al₂O₃) to the sodium borohydride (NaBH₄) powder as the two types of reducing agents had a specific resistance value measured at 4.5×10⁹ Ω·cm to 5.0×10¹¹ Ω·cm, and it may be seen that the specific resistance value may be controlled to 10¹² Ω·cm or less by the reduction treatment. Particularly, the use of two or more types of reducing agents including sodium borohydride (NaBH₄) powder seems to be more effective in charging suppression since the substrate has a larger degree of reduction compared to the substrate subjected to reduction treatment using sodium borohydride (NaBH₄) powder alone.

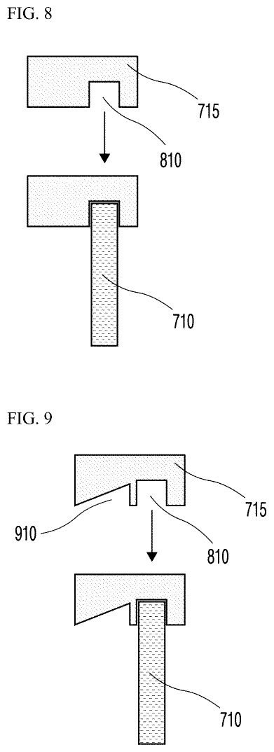

FIG. 6 shows photographs of surfaces states of the lithium tantalate single crystal substrates that had undergone post-treatment using the composite reducing agent according to one embodiment of the present disclosure and the lithium tantalate single crystal substrate of Comparative Example.

Referring to FIG. 6, it may be seen that the substrates of Examples are colored compared to the lithium tantalate (LT) single crystal substrate that had not undergone reduction treatment of Comparative Example. The color of the substrate when using sodium borohydride (NaBH₄) powder and lithium carbonate (Li₂CO₃) powder as the reducing agent changes to opaque black, and it may be seen that light transmission may be sufficiently suppressed.

In addition, in Example 6 using sodium borohydride (NaBH₄) powder and aluminum oxide (Al₂O₃) powder as the reducing agent, it may be identified that the color of the substrate also changes to gray-black, indicating that there is no significant difference from the substrates that had undergone reduction treatment of Examples 1 to 5. Since the substrate that had undergone reduction treatment of Example 6 was also changed to an opaque state, it is interpreted that light transmittance may be suppressed in the substrate that had undergone reduction treatment of Example 6 as well.

The results on the lithium tantalate (LT) single crystal substrates of Examples show that the post-treatment method of the lithium tantalate (LT) single crystal substrate of the present disclosure using sodium borohydride (NaBH₄) or at least two or more types of reducing agents including sodium borohydride (NaBH₄) may sufficiently control the degree of reduction of the lithium tantalate (LT) single crystal substrate through heat treatment for 3 hours to 5 hours under normal pressure at a temperature of 300° C. to 400° C.

The post-treatment method of the lithium tantalate (LT) single crystal substrate of the present disclosure and the method for manufacturing the lithium tantalate (LT) single crystal substrate based thereon may perform reduction treatment of the substrate in a short period of time in a relatively mild environment compared to existing environments required for reducing a lithium tantalate (LT) single crystal substrate, and therefore, post-treatment of the lithium tantalate (LT) single crystal substrate may be performed in a simple and safe manner.

Hereinafter, a device for growing the lithium tantalate (LT) single crystal according to one embodiment of the present disclosure will be described.

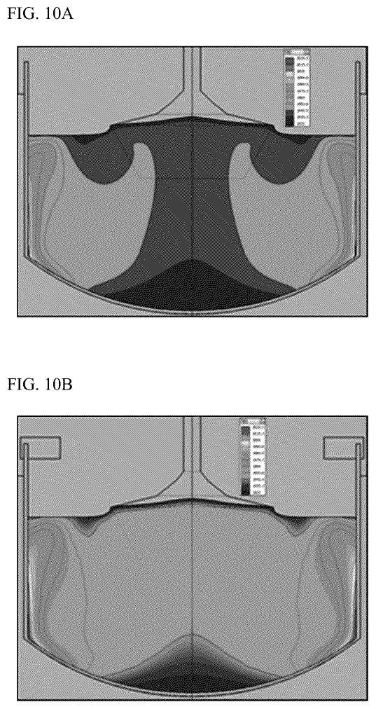

FIG. 7 is a diagram illustrating a configuration of a device for single crystal growth according to one embodiment of the present disclosure.

Referring to FIG. 7, the device for single crystal growth 700, (hereinafter, abbreviated as ‘device’) according to one embodiment of the present disclosure includes a crucible 710, a cover 715, a crucible support unit 720, a first seed 730, a second seed 740, a heater 750, an insulating material 760, a housing 770 and a control unit (not shown).

The crucible 710 receives and melts a raw material of a material to be grown into a single crystal, so that the melted solution grows to a single crystal by the seed. The crucible 710 may be made of various materials depending on the type of material to be grown into a single crystal and a growth temperature thereof, and may be representatively made of platinum (Pt), platinum rhodium (PtRh), iridium (Ir), carbon or molybdenum (Mo).

As an important factor in growing the melted solution into a single crystal, there are two factors of a crystal pulling speed (by the seed) and a crystal rotation speed (by the seed). These are not independent variables, but are closely related to the temperature distribution inside the device 700. Accordingly, it is preferred to minimize heat release inside the device 700, particularly, the crucible 710.

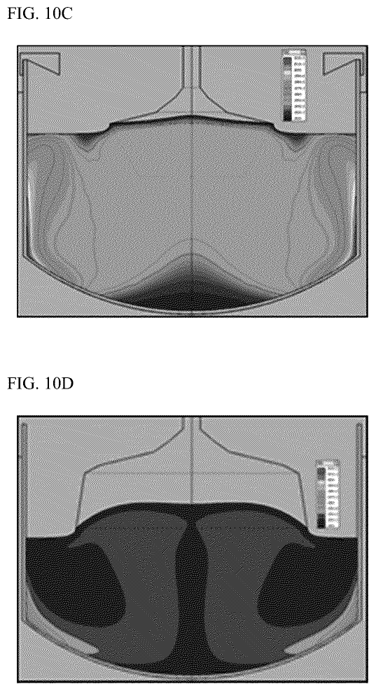

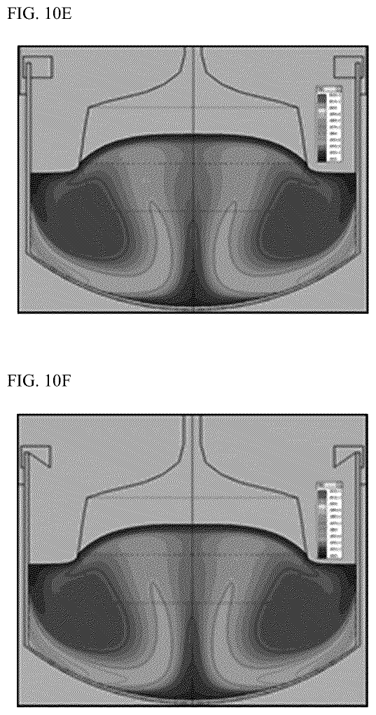

Accordingly, a cover 715 having a ring shape is disposed on the top of the crucible 710. The cover 715 has a structure illustrated in FIG. 8 or FIG. 9, thereby minimizing heat release from the crucible 710 to the outside.

FIG. 8 is an enlarged diagram of a portion of the crucible for single crystal growth according to one embodiment of the present disclosure.

Referring to FIG. 8, the cover 715 according to one embodiment of the present disclosure is embodied in a ring shape including a groove 810. The groove 810 is embodied on one surface of the cover 715 facing the crucible 710 with a width equal to the thickness of the outer wall of the crucible 710. Accordingly, the cover 715 may be seated on the top of the crucible 710. While being seated, the cover 715 may protrude from the top of the crucible 710 to the inside (direction toward the center of the crucible) by a preset length.

Herein, the cover 715 is made of a material having low thermal conductivity (below a preset standard value). Accordingly, as the cover 715 protrudes from the top of the crucible 710 to the inside of the crucible 710 by a preset length, release of heat discharged from the crucible 710 to the outside of the crucible 710 may be blocked. As the cover 715 is embodied in a ring shape, the above-described effect may be achieved without affecting ascending/descending of the seeds 730, 740.

Alternatively, the cover 715 may have a structure illustrated in FIG. 9.

FIG. 9 is an enlarged diagram of a portion of the crucible for single crystal growth according to another embodiment of the present disclosure.

Referring to FIG. 9, the cover 715 according to one embodiment of the present disclosure is embodied in a ring shape including a groove 810 and a heat reflecting unit 910.

The heat reflecting unit 610 is embodied adjacent to the groove 810 on the one surface on which the groove 810 is embodied in the cover 715. The heat reflecting unit 910 has a caved-in shape on the corresponding surface of the cover 715 so as to have a slope in a form of gradually deepening into the cover 715. Accordingly, the heat reflecting unit 910 blocks a release of heat discharged from the crucible 710 to the outside of the crucible 710, and, in blocking the heat release, may intensively release heat outwardly far from the center of the crucible 710.

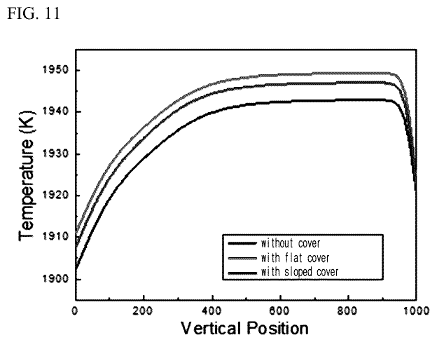

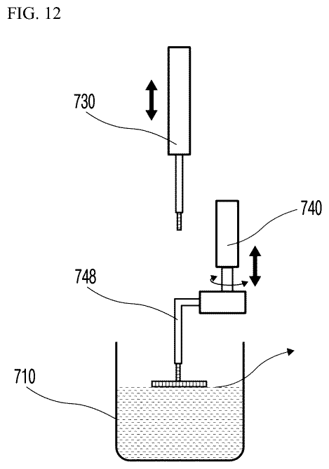

As the cover 715 is disposed on the top of the crucible 710 as above, effects shown in FIG. 10 and FIG. 11 may be obtained. FIGS. 10A to 10F are diagrams showing temperature distribution inside the crucible for single crystal growth during the process in which the device for single crystal growth according to one embodiment of the present disclosure grows a single crystal.

FIG. 10A shows temperature distribution (inside the crucible) when the cover 715 is not disposed in a case where the single crystal growth length is 30 mm, FIG. 10B shows temperature distribution (inside the crucible) when the cover 715 according to one embodiment of the present disclosure is disposed under the same circumstance, and FIG. 10c shows temperature distribution (inside the crucible) when the cover 715 according to another embodiment of the present disclosure is disposed under the same circumstance.

Referring to FIG. 10A to FIG. 10C, it may be identified that the temperature inside the crucible 710 is relatively high in FIG. 10B or FIG. 10C compared to in FIG. 10A.

FIG. 10D shows temperature distribution (inside the crucible) when the cover 715 is not disposed in a case where the single crystal growth length is 5 mm, FIG. 10E shows temperature distribution (inside the crucible) when the cover 715 according to one embodiment of the present disclosure is disposed under the same circumstance, and FIG. 10F shows temperature distribution (inside the crucible) when the cover 715 according to another embodiment of the present disclosure is disposed under the same circumstance.

Referring to FIG. 10D to FIG. 10F, it may be identified that the temperature inside the crucible 710 is relatively high in FIG. 10E or FIG. 10F compared to in FIG. 10D in this case as well. This may also be identified in FIG. 11.

FIG. 11 is a graph showing temperature distribution of the melt in the crucible for single crystal growth according to one embodiment of the present disclosure.

Referring to FIG. 11, it may be identified that the temperature distribution of the melt when the cover 715 is disposed on the top of the crucible 710 (in a vertical direction inside the crucible) is relatively higher than the temperature distribution of the melt when the cover 715 is not present. In other words, it may be identified that heat release is reduced by the cover 715, and the temperature of the melt inside the crucible 710 becomes relatively higher.

Referring to FIG. 7 again, the crucible support unit 720 includes a groove having the same size as the crucible 710, and seats the crucible 710 inside itself for support. Meanwhile, the crucible support unit 720 has a structure capable of rotating, and may rotate the crucible 710 seated on itself together with itself. The rotation direction of the crucible support unit 720 may be opposite to the direction in which each seed 730, 740 rotates to grow a crystal. The crucible support unit 720 rotates in the direction described above, allowing each seed 730, 740 to grow a crystal more smoothly.

The first seed 730 grows the melted solution in the crucible 710 into a crystal while ascending/descending and rotating. The first seed 730 ascends/descends in a vertical direction, and may descend to the surface of the melted solution in the crucible 710 or ascend in a direction away therefrom. The first seed 730 is brought into contact with the surface of the melted solution in the crucible 710 under the control of the control unit (not shown), and ascends at a preset first speed after the contact. Meanwhile, the first seed 730 may rotate separately from ascending/descending. Particularly, the first seed 730 may rotate in a direction opposite to the direction in which the crucible support unit 720 rotates. During the process in which the first seed 730 ascends at a preset first speed after being brought into contact with the surface of the melted solution, the first seed 730 may rotate at the same time at a preset second speed. Accordingly, the melted solution ascends along the first seed 730 and grows into a single crystal.

The second seed 740 grows impurities included in the melted solution in the crucible 710 into a crystal while ascending/descending and rotating. The second seed 740 includes a body 742, a connection unit 744, a rotation axis 746 and a contact unit 748.

The body 742 is connected to each component in the second seed 740, and ascends/descends and rotates. The body 742 is connected to the connection unit 744 by the rotation axis 746. Accordingly, when the body 742 ascends/descends, the connection unit 744 and the contact unit 748 ascend/descend therewith.

When the body 742 rotates, the connection unit 744 rotates around the rotation axis 746. Accordingly, the contact unit 748 bound to the connection unit 744 also rotates together.

The connection unit 744 is connected to the body 742 by the rotation axis 746 on one surface, and connected to the contact unit 748 on the other surface. The connection unit 744 connects the two 742, 748, moves by the power transferred from the body 742, and also moves the contact unit 748 together therewith.

The rotation axis 746 connects the body 742 and the connection unit 744. The rotation axis 746 connects the two 742, 744, and transfers rotational power transferred from the body 742 to the connection unit 744, allowing the connection unit 744 to rotate.

The contact unit 748 is connected to one surface of the connection unit 744, particularly, one surface closest to the crucible 710 of the connection unit 744, allowing impurities included in the melted solution in the crucible 710 to grow into a crystal. The contact unit 748 is connected to the corresponding position, and disposed to face the crucible 710, particularly, the central portion of the crucible 710. The contact unit 748 may be embodied in a bent form as illustrated in FIG. 7 so as to be disposed to face the central portion of the crucible 710. Accordingly, the contact unit 748 ascends/descends in a vertical direction together with the connection unit along the movement of the connection unit 744, and may descend to the surface of the melted solution in the crucible 710 or ascend in a direction away therefrom. In addition, the contact unit 748 rotates together with the rotation of the connection unit 744, and may be positioned to face the central portion of the crucible 710 or positioned in a direction away from the crucible 710. When the contact unit 748 is positioned to face the central portion of the crucible 710, the contact unit 748 is brought into contact with the melted solution in the crucible 710 so as to grow impurities included therein into a crystal. Meanwhile, when the contact unit 748 is positioned in a direction away from the crucible 710, the first seed 730 is allowed to grow the melted solution in the crucible 710 into a crystal.

The heater 750 is disposed on the outer side of the crucible support unit 720, and heats the crucible 710. The heater 750 heats the crucible 710 so that the crucible 710 or the melted solution in the crucible 710 has a temperature suitable to grow into a crystal.

The insulating material 760 is disposed on the outer side (direction away from the crucible) of the heater 750 to minimize the heat, which is released from the heater 750, from being released in a direction away from the crucible 710.

The housing 770 is disposed on the outermost side of the device 700, and separates the components inside the device 700 from the outside.

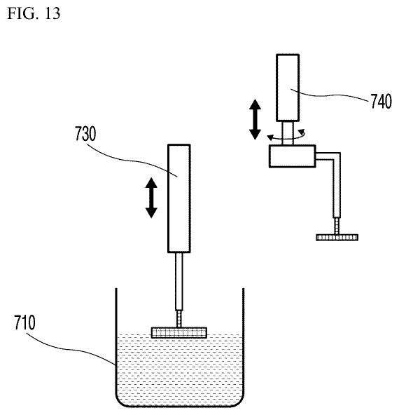

The control unit (not shown) controls the operation of each component in the device 700 as illustrated in FIGS. 12 and 13 in order to grow the melted solution loaded into the crucible 710 into a single crystal.

FIGS. 12 and 13 are diagrams illustrating a single crystal growth process in the device for single crystal growth according to one embodiment of the present disclosure.

As illustrated in FIG. 12, the control unit (not shown) controls the operation of the second seed 740 prior to the operation of the first seed 730. The control unit (not shown) rotates and then lowers the body 742 so that the contact unit 748 in the second seed 740 is brought into contact with the melted solution in the crucible 710 while facing the central portion of the crucible 710. When the melted solution in the crucible 710 is loaded and is subjected to a temperature increase or has a suitable temperature by the heater 750, the melted solution rotates and convects. In this process, impurities in the melted solution are concentrated in the central portion of the upper portion, and the concentration of the impurities increases in the corresponding portion. Accordingly, the control unit (not shown) controls the contact unit 748 in the second seed 740 to be brought into contact with the melted solution in the crucible 710 while facing the central portion of the crucible 710.

When the contact unit 748 in the second seed 740 is brought into contact with the central portion of the crucible 710, the control unit (not shown) raises the body 742 so that the contact unit 748 ascends at a preset first speed. Accordingly, a crystal including most of the impurities grows along the second seed 740. Herein, the control unit (not shown) may control the crucible support unit 720 to rotate so that a crystal including the impurities grows smoothly.

When the growth of a crystal including the impurities is completed as the second seed 740 ascends, the control unit (not shown) controls the body 742 in the second seed 740 so that the contact unit 748 moves away from the crucible 710.

After that, the control unit (not shown) lowers the first seed 730 so that the first seed 730 is in contact with the melted solution. When the first seed 730 is in contact with the melted solution, the control unit (not shown) raises the first seed 730 at a present first speed while rotating the first seed 730 at a preset second speed. Accordingly, a single crystal having impurities excluded to the maximum extent may be manufactured.

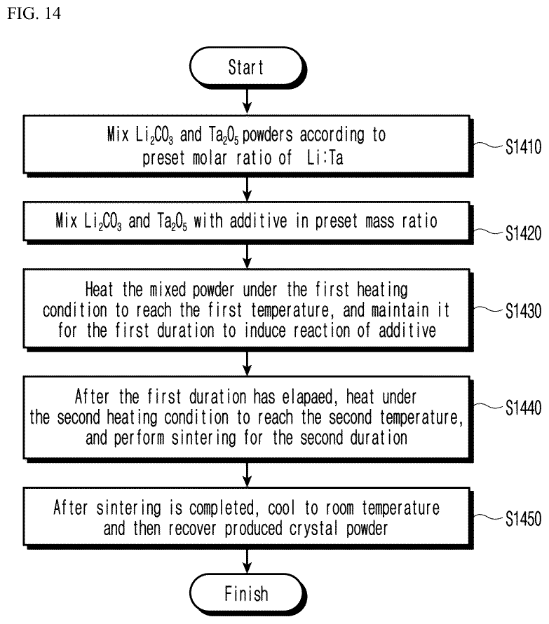

FIG. 14 is a flow chart illustrating a method for manufacturing a lithium tantalate (LT) raw material powder according to one embodiment of the present disclosure.

The method for manufacturing a lithium tantalate (LT) raw material powder of the present disclosure performs synthesis using a solid-state combustion method, and is capable of inducing a reaction at a relatively low sintering temperature and in a short period of time by using an additive for the starting materials while relatively simplifying the manufacturing process, and as a result, production efficiency is improved.

In addition, a lithium tantalate (LT) raw material powder synthesized as above exhibits high purity and high crystallinity, inducing uniform nucleation in the growth of a lithium tantalate (LT) single crystal, a piezoelectric oxide, and improving a growth rate of the crystal, and therefore, the powder is suitable to be used in a high-performance SAW filter.

Accordingly, by going through a manufacturing process to be described later, the lithium tantalate (LT) powder according to one embodiment of the present disclosure may be manufactured into a raw material of a lithium tantalate (LT) single crystal having excellent crystallinity just by applying a simple process compared to existing solid-state synthesis methods.

Starting materials are mixed according to a preset molar ratio (S1410).

As the starting materials, lithium carbonate (Li₂CO₃) and tantalum pentoxide (Ta₂O₅) are used.

The present disclosure employees a solid-state combustion synthesis method, and therefore, raw materials in a solid state, that is, in a powder state need to be used as the starting materials. Accordingly, lithium carbonate (Li₂CO₃) and tantalum pentoxide (Ta₂O₅) in powder states are preferably used. Accordingly, lithium carbonate (Li₂CO₃) and tantalum pentoxide (Ta₂O₅) may additionally undergo a separate grinding process as needed.

As described above, a congruent ratio is very important for a lithium tantalate (LT) single crystal as a SAW filter material, and when this ratio is not appropriate, physical and chemical properties of the single crystal may be deformed or damaged. Herein, the congruent ratio means an exact ratio between lithium (Li) and tantalum (Ta) elements in a state having the same solid phase and liquid phase compositions during a crystal growth process, and it is generally known that the most ideal quality and performance of a single crystal are obtained when the ratio between lithium (Li) and tantalum (Ta) is 48.3 to 50.0:50.0 to 51.7.

Accordingly, it is preferred that the starting materials of the present disclosure are mixed in a molar ratio of Li:Ta=48.3 to 50.0:50.0 to 51.7.

An additive is mixed into the mixture of starting materials in a preset mass ratio (S1420).

By introducing an additive to the mixture of starting materials and using the result in a solid-state combustion process, the present disclosure addresses the issue that it is difficult to maintain an exact ratio between starting materials due to high-temperature treatment during a combustion process in the related art, thereby improving heat treatment efficiency and chemical reaction efficiency.

A solid-state combustion synthesis method does not use materials in a liquid state in general and is thereby capable of preventing impurities from being mixed thereinto, which is suitable to synthesize high-purity ceramic raw materials. However, the solid-state combustion synthesis method has a disadvantage of a slow reaction rate compared to liquid-phase synthesis using a solvent.

Therefore, in the present disclosure, an additive is heat treated and sintered together with the starting materials, and heat energy required for the starting materials to undergo a chemical reaction is supplied by a decomposition reaction of the additive. For this, materials capable of, as a material that does not react with the starting materials, functioning as a fuel may be used as the additive of the present disclosure, and materials in a powder state are preferred.

For example, the additive introduced to the starting materials in the present disclosure may be cyanuric acid (CHON)₃. Cyanuric acid is decomposed by an exothermic reaction releasing energy during the decomposition process. Cyanuric acid (CHON)₃ is in a powder state and has a melting point (MP) of 320° C. to 360° C., and is decomposed into carbon and nitrogen at 800° C. or higher after going through dehydration and tricycle decomposition processes. Heat energy released during this decomposition process may be used as energy for a sintering process of the starting materials.

The additive used as fuel after being mixed into the starting materials and used together therewith in a sintering process to be described later is a material having high exothermic reactivity, and materials that starting materials do not react with for products in the melting or decomposing process of the additive are preferably used. In addition, it is preferred to use materials that does not leave residues so as not to affect purity of a synthesis product to be finally obtained.

As for the preset ratio in which the additive is mixed into the starting materials, the mixture of starting materials and the additive may be mixed in a range of 1:3 to 1:5 as a mass ratio based on the starting materials in which lithium carbonate (Li₂CO₃) and tantalum pentoxide (Ta₂O₅) are mixed in a molar ratio of Li:Ta=48.3 to 50.0:50.0 to 51.7, and it is more preferred that the starting materials and the additive are mixed in a ratio of 1:4 as a mass ratio.

When the ratio of the introduced additive is less than 1:3 with respect to the mass of the starting materials, the molar ratio of lithium (Li) and tantalum (Ta) in a finally formed lithium tantalate (LT) powder may change. In addition, when the additive is introduced in excess at an introduction ratio of greater than 1:5, the starting materials may be present unreacted. Accordingly, the mixing ratio of the additive and the starting materials is very important in the quality of a lithium tantalate (LT) powder to be finally obtained.

The mixed powder in which the starting materials and the additive are mixed is introduced to an electric furnace, heated under a first heating condition to reach the first temperature, and then kept it for the first duration to induce the reaction of the additive (S1430).

The first temperature at which the reaction of the additive is induced is preferably set to a temperature for the decomposition reaction of the additive. Since the additive of the present disclosure is an inducing agent lowering the reaction temperature of lithium carbonate and tantalum pentoxide as fuel, a first sintering process, the reaction of exothermically decomposing the additive, is performed first.

For example, when the additive is cyanuric acid (CHON)₃, the first temperature at which the mixed powder of the starting materials and the additive introduced to the electric furnace is first heat treated may be in a range of 400° C. to 550° C., and is more preferably 450° C. to 500° C. The first heating condition to raise the temperature to the first temperature is 300° C./hour, and the first sintering process at the first temperature may be performed for 2 hours. In addition, the first sintering may be performed under the normal pressure atmosphere.

The conditions for the first sintering process to induce the exothermic reaction of the additive may be derived from the results of analyzing the thermal response for the mixed powder of the additive and the starting materials.

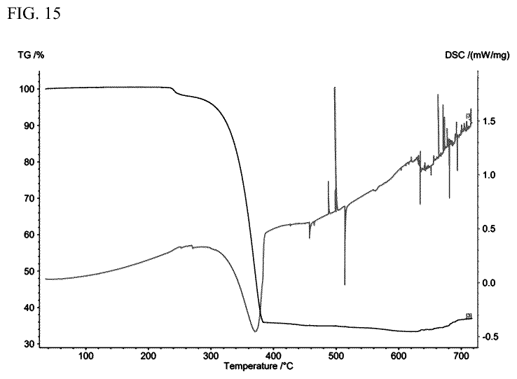

FIG. 15 shows a result of thermogravimetric-differential scanning calorimetry (TG-DSC) for analyzing the thermal response of the raw material mixture for manufacturing the lithium tantalate raw material powder according to one embodiment of the present disclosure.

Referring to FIG. 15, it may be identified that a significant exothermic peak is formed around 370° C. in the DSC trend shown in red. In addition, according to the weight curve, it may be seen that a decrease in the mixed powder weight begins to occur around 250° C. at which the exothermic peak begins to form, a rapid weight decrease occurs around 370° C., and almost no substantial weight decrease occurs at a temperature of 390° C. or higher at which the exothermic reaction is finally finished.

Herein, the exothermic peak around 370° C. is due to the decomposition reaction of cyanuric acid used as the additive, and the weight decrease at the exothermic peak may be interpreted as a result of the decomposition of cyanuric acid. During the exothermic reaction due to the decomposition of the additive, a rapid weight decrease of 60% or greater of the total weight occurred. In addition, it may be seen that there is no significant change in the mass after 450° C. at which the exothermic reaction is almost finished.

Accordingly, the present disclosure is capable of controlling the first temperature condition in a range of 450° C. to 500° C. considering a temperature at which the exothermic reaction of cyanuric acid occurs as the first sintering condition for inducing the exothermic reaction of the additive.

When the first sintering is completed at the first temperature condition for the first duration, the temperature is raised to a second heating condition, and sintering is performed at the second temperature (S1440).

When the reaction of the additive is sufficiently induced in the first sintering, second sintering is performed after raising the temperature to the second temperature under the second temperature-raising condition, and the lithium tantalate (LT) powder is synthesized in the second sintering.

When synthesizing a lithium tantalate (LT) powder using a general solid-state combustion method, sintering is performed for at least 8 hours, and up to 48 hours at a temperature of 1000° C. or higher.

However, by using an additive generating exothermic energy during the decomposition process as a type of fuel, the present disclosure is capable of synthesizing a lithium tantalate (LT) powder at a relatively lower temperature compared to an existing sintering temperature for synthesizing a lithium tantalate (LT) powder.

More specifically, as exothermic energy, which is generated by sufficiently performing the reaction of the additive during the first sintering, is used in the reaction of lithium carbonate and tantalum pentoxide in solid states, the second temperature at which a lithium tantalate (LT) powder is synthesized during the second sintering process of the present disclosure may be selected in a range of 800° C. to 900° C., and more preferably, the sintering may be performed at a temperature of 850° C. to 870° C. for 1 hour under the normal pressure atmosphere.

In addition, the temperature may be raised from the first temperature to the second temperature at a rate of 300° C./hour.

Referring to the results of DSC analyses of FIG. 15, occurrences of small-scale endothermic and/or exothermic reactions may be identified at 600° C. or higher, and this is considered to be a result of a reaction for producing a lithium tantalate (LT) crystal. Herein, the second temperature for the second sintering is controlled in a range of 800° C. to 900° C. in order to improve purity and uniformity of the produced lithium tantalate (LT) crystal, and to accomplish a stoichiometric molar ratio of 1:1 between Li and Ta in the powder.

After the second sintering is completed, the result is cooled to room temperature, and then the produced lithium tantalate (LT) crystal powder is recovered (S1450).

Hereinafter, characteristics of the lithium tantalate (LT) powders each manufactured using an existing solid-state combustion method and the synthesis method according to one embodiment of the present disclosure will be specifically examined.

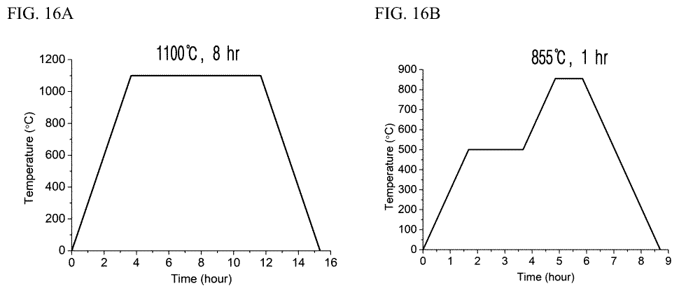

FIGS. 16A and 16B are diagrams showing a temperature profile of the heat treatment process for the manufacturing method of the lithium tantalate raw material powder according to one embodiment of the present disclosure and the manufacturing process according to Comparative Example.

FIG. 16A shows a temperature profile of the heat treatment process for the manufacturing method of Comparative Example, and FIG. 16B shows a temperature profile for the heat treatment process in the manufacturing method of one embodiment of the present disclosure.

In the synthesis of the lithium tantalate (LT) raw material powder, lithium carbonate (Li₂CO₃) and tantalum pentoxide (Ta₂O₅) powders were included in a molar ratio of Li:Ta=50:50 as starting materials, and cyanuric acid (CHON)₃ was used as an additive. The cyanuric acid (CHON)₃ powder and the mixed powder of starting materials were introduced in a ratio of 4:1 based on the mass, and the amounts of the starting materials and the additive were used identically for Comparative Example and Example.

Comparative Example uses a solid-state combustion method without using the additive, and the sintering process was performed at a temperature of 1100° C. under the normal pressure atmosphere maintained for 8 hours, and the heating rate was controlled to 300° C./hour.

Meanwhile, the method for synthesizing the lithium tantalate (LT) powder of one embodiment of the present disclosure was performed by steps S1410 to S1450 described above.

Herein, the first sintering was maintained for 2 hours at a temperature of 500° C. under the normal pressure atmosphere, and the second sintering was maintained for 1 hour at a temperature of 855° C. under the normal pressure atmosphere, and each of the sintering processes was controlled at a heating rate of 300° C./hour.

Referring to FIGS. 16A and 16B, it may be seen that, in the sintering process of Comparative Example, an existing method, a series of the heat treatments including the temperature-raising and cooling processes took a total of 15.2 hours including 8 hours maintained at the set sintering temperature.

On the other hand, the sintering process of Example including the additive had a total heat treatment time of 8.7 hours including the first and the second sintering processes, and all the temperature-raising and cooling processes performed for each sintering, and shortened heat treatment time by 40% or greater compared to Comparative Example that did not use the additive.

In other words, by utilizing heat energy from the exothermic reaction of cyanuric acid (CHON)₃, it is possible to lower the heat treatment temperature for sintering from 1100° C. to 855° C., and shorten the time taken for the reaction by 40% or greater as well, and accordingly, the use of energy required for producing a lithium tantalate (LT) powder may be reduced by using the additive.

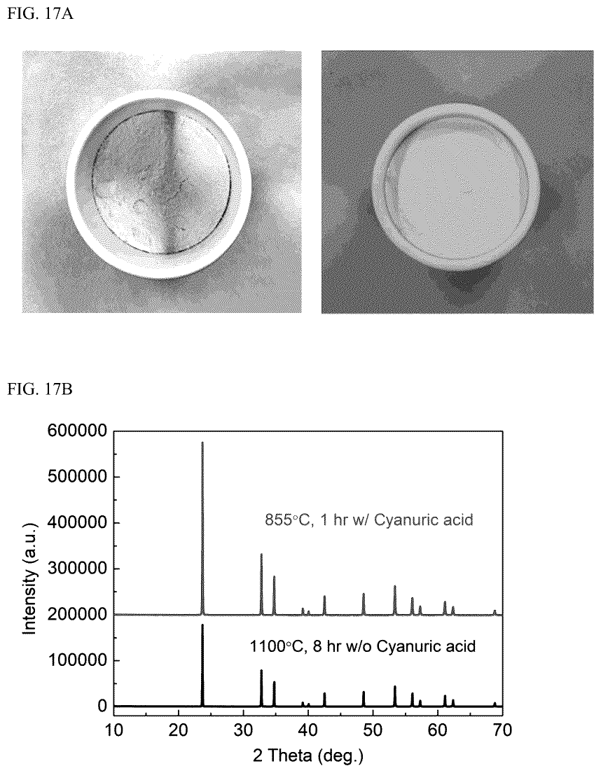

From such differences in the reaction processes, results on properties of the lithium tantalate (LT) powder, a synthesized final product, will be described in FIGS. 17 to 19.

FIGS. 17A and 17B show photographs of the lithium tantalate raw material powders manufactured using the manufacturing method according to one embodiment of the present disclosure and the manufacturing method according to Comparative Example, and results of analyzing the powder compositions and the crystal states by X-ray diffraction analysis (XRD).

FIG. 17A shows photographs of the powders each manufactured from the manufacturing methods of Comparative Example and Example, and FIG. 17B shows results of XRD analyses comparatively measured with the same mass for each of the powders.

Referring to FIG. 17A, it may be seen that the synthesized lithium tantalate (LT) powder crystal is formed as white powder regardless of the use of an additive and the resulting differences in the sintering temperature and the reaction time, and there are no significant differences between the two when observed with the naked eye.

Meanwhile, referring to the XRD analysis results of FIG. 17B, the lithium tantalate (LT) powder manufactured from the manufacturing method of Example using an additive and the powder of Comparative Example manufactured from an existing general sintering method were all measured to have the same XRD peak, and as a result, it may be identified that lithium tantalate having a crystalline structure formed with a single phase of LiTaO₃ is formed through the synthesis methods of both Comparative Example and Example.

Particularly, it may be seen that the manufacturing method of Example of FIG. 17B does not have problems such as further detection of additional impurities or detection of unreacted residues due to the use of cyanuric acid, even when the heat treatment was performed with cyanuric acid further included as an additive.

In addition, it may be seen that the size of XRD peak for the powder of the Example (FIG. 17B, 855° C., 1 hour w/cyanuric acid) appears to be larger than the size of XRD peak for the powder of Comparative Example (FIG. 17B, 1100° C., 8 hours w/o cyanuric acid), and it may be interpreted as the lithium tantalate (LT) powder synthesized using an additive in the present disclosure having more superior crystallinity or having more crystals formed compared to the lithium tantalate (LT) powder formed by sintering at a high temperature for a long period of time.

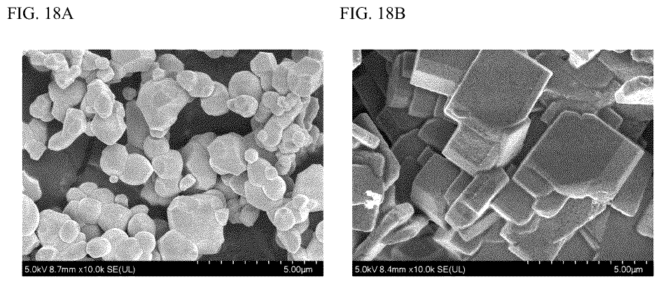

FIGS. 18A and 18B show results of measuring the lithium tantalate (LT) raw material powders manufactured using the manufacturing method according to one embodiment of the present disclosure and the manufacturing method of Comparative Example using a scanning electron microscope (SEM).

FIG. 18A shows the result of SEM measurement for the powder manufactured from the manufacturing method of Comparative Example, and FIG. 18B shows the result of SEM measurement for the powder manufactured by the manufacturing method of Example.

Referring to FIGS. 18A and 18B, it may be identified that the particles of the powder according to the manufacturing method of Example are larger than the particles of the powder of Comparative Example.

Table 3 summarizes the particle sizes of each powder analyzed from the results of SEM measurements of FIGS. 18A and 18B.

TABLE 3

| Category | Comparative Example | Example |
|---|---|---|
| Mean Particle | 1.186 μm | 3.252 μm |
| Size | | |
| (Mean) | | |
| Standard | 0.501 μm | 1.307 μm |
| Deviation | | |
| Minimum Size | 0.339 μm | 2.148 μm |
| (Min) | | |
| Maximum Size | 2.235 μm | 4.849 μm |
| (Max) | | |

Examining Table 3, it may be numerically identified that the lithium tantalate (LT) powder of Example synthesized by heat treatment at a relatively low temperature and in a short period of time using an additive has a lager particle size, as may be identified in the photographs of SEM measurements. This result is also consistent with the XRD analysis results of FIG. 17 described above.

The manufacturing method of the present disclosure supplies sufficient heat energy for the crystallization reaction of lithium carbonate and tantalum pentoxide using an exothermic reaction of an additive, and therefore, despite applying a relatively low reaction temperature and a short reaction time as a condition for sintering, the method is capable of synthesizing a high-quality raw material having excellent crystallinity compared to the powder synthesized over a long period of time at a high temperature.

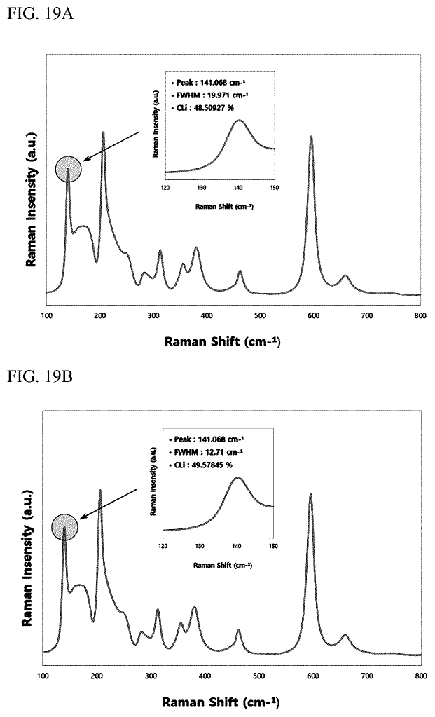

FIGS. 19A and 19B show results of Raman spectroscopy measurements analyzing the compositions of the lithium tantalate (LT) raw material powders manufactured using the manufacturing method according to one embodiment of the present disclosure and the manufacturing method according to Comparative Example.

FIG. 19A shows a Raman spectrum of the powder manufactured from the manufacturing method of Comparative Example, and FIG. 19B shows a Raman spectrum of the powder manufactured using the manufacturing method of Example.

From the results of Raman spectra, the chemical composition of the lithium tantalate (LT) powder manufactured from each of the synthesis methods may be quantified.

Referring to FIGS. 19A and 19B, there is no significant difference in the peaks of the Raman spectra for each of the powders synthesized by Comparative Example and Example. However, the most important peak in a Raman spectrum for a lithium tantalate (LT) crystal is phonon appearing at 140 cm⁻¹, which indicates an energy level corresponding to a specific vibration mode of a lithium tantalate crystal lattice, significantly affecting physical and chemical properties of the crystal.

Since a Raman absorption band at 140 cm⁻¹ measured for the lithium tantalates of Example and Comparative Example of FIGS. 19A and 19B is clearly identified, a full width at half peak (FWHP) at the corresponding peak of the lithium tantalate crystal may be derived therefor, and using the value, the stoichiometric composition of the lithium tantalate (LT), that is, the ratio between lithium (Li) and tantalum (Ta) may be identified.

In the lithium tantalate (LT) according to Comparative Example of FIG. 19A, the FWHP at 140 cm⁻¹ was 19.971 cm⁻¹, and the Li content (C_{Li}) calculated therefrom was 48.5%, indicating that a loss of about 3% occurred based on Li.

On the other hand, in the lithium tantalate (LT) synthesized using the manufacturing method of Example, the FWHP at 140 cm⁻¹ was 12.71 cm⁻¹, and the Li content (C_{Li}) calculated therefrom was 49.6%, which actually indicates a higher lithium composition compared to in the lithium tantalate (LT) of Comparative Example, and the ratio of Li loss was less than 1%.

Such a difference in the lithium content may be considered to result from the fact that LiO₂ is relatively more volatized as the sintering is performed for a long period of time at a high temperature of 1100° C. in the synthesis method of Comparative Example.

In addition, the lithium content in the lithium tantalate (LT) synthesized using the additive in Example was measured to be 49.6%, and considering that the starting materials were introduced in a molar ratio of Li:Ta=50:50, it may be seen that the lithium tantalate synthesized from the manufacturing method of Example was formed into a higher-quality powder with a stoichiometric ratio close to 1:1.

As shown in the results of XRD analyses and SEM measurements described above, the method for manufacturing a lithium tantalate (LT) powder of the present disclosure is capable of synthesizing a high-quality lithium tantalate (LT) powder compared to the synthesis using an existing solid-state combustion method even when performing heat treatment for a short period of time at a relatively low temperature.

Particularly, the lithium tantalate (LT) powder obtained from the manufacturing method of the present disclosure is capable of obtaining a crystal with perfect quality even in stoichiometric terms, and therefore, is sufficient to be used as a raw material for growing a single crystal for a SAW filter.

In the method for manufacturing a lithium tantalate raw material powder of the present disclosure, an exothermic decomposition reaction of the additive assists heat energy for the chemical reaction of the starting materials, reducing the amount of heat energy required to be supplied from the outside for the manufacture of the lithium tantalate (LT) raw material powder, and therefore, the process may be simplified and the production costs may be reduced compared to synthesis methods using existing chemical synthesis and solid-state combustion. In addition, since the heat treatment is performed for a short period of time at a relatively low temperature, the process for achieving the chemical composition of lithium tantalate may be controlled in a much simpler and safer manner compared to existing synthesis methods.

In FIGS. 4 to 14, it is described that each process is sequentially performed, however, this is just an illustrative explanation on the technical idea of one embodiment of the present disclosure. In other words, those skilled in the art may make various modifications and changes such as changing the order of the processes described in each drawing or performing one or more of the processes in parallel without departing from essential characteristics of one embodiment of the present disclosure, and therefore, FIGS. 4 to 14 are not limited to a time sequential order.

The above description is just an illustrative explanation on the technical idea of the present embodiment, and those skilled in the art may make various modifications and changes without departing from essential characteristics of the present embodiment. Accordingly, the present embodiments are to explain the technical idea of the present embodiment rather than limiting the technical idea of the present embodiment, and the scope of technical idea of the present embodiment is not limited by such embodiments. The scope of protection of the present embodiment needs to be interpreted in accordance with the claims, and all technical ideas within an equivalent scope thereto need to be interpreted as being included in the scope of right of the present embodiment.

What is claimed is:

1. A post-treatment method of a piezoelectric oxide single crystal substrate for suppressing pyroelectric properties of the substrate, the method comprising:
loading at least one reducing agent and the single crystal substrate into a treatment device; and
performing reduction treatment by heat treating the substrate while maintaining the inside of the treatment device in a preset environment,
wherein the preset environment means that heat treatment is performed at a temperature of 200° C. to 400° C. under normal pressure.

2. The method of claim 1, wherein the piezoelectric oxide single crystal substrate is a lithium tantalate (LT) single crystal substrate.

3. The method of claim 1, wherein the performing of reduction treatment by heat treating the substrate is performing heat treatment for 3 hours to 5 hours.

4. The method of claim 1, wherein the at least reducing agent includes sodium borohydride (NaBH₄) in a powder state.

5. The method of claim 4, wherein the at least one reducing agent further includes any one or more selected from lithium carbonate (Li₂CO₃), iron (Fe) and aluminum oxide (Al₂O₃).

6. The method of claim 4, wherein the reduced substrate is controlled to have a specific resistance value of greater than 10⁹ Ω·cm and less than 1013 Ω·cm.

7. The method of claim 1, wherein the performing of reduction treatment by heat treating the substrate is performed under an air or inert gas atmosphere.

8. The method of claim 1, wherein the loading of at least one reducing agent and the single crystal substrate into a treatment device is performed by disposing the at least one reducing agent and the at least one single crystal substrate separately in a treatment device, or embedding the at least one single crystal substrate in the at least one reducing agent.

9. A method for manufacturing a lithium tantalate (LT) single crystal substrate, the method comprising:
growing a lithium tantalate (LT) single crystal and processing the crystal into a substrate state;
loading the processed lithium tantalate (LT) single crystal substrate and at least one reducing agent into a treatment device; and
performing reduction treatment by heat treating the substrate while maintaining the inside of the treatment device in a preset environment,
wherein the preset environment means that heat treatment is performed for 3 hours to 5 hours at a temperature of 200° C. to 400° C. under normal pressure.

10. The method of claim 9, wherein the at least one reducing agent includes sodium borohydride (NaBH₄) in a powder state.
